(19) United States
(12) Patent Application Publication
(10) Pub. No.: US 2008/0041434 A1
(43) Pub. Date: Feb. 21, 2008

(54) METHODS AND DEVICES FOR LARGE-SCALE SOLAR INSTALLATIONS

(75) Inventors: Paul Adriani, Palo Alto, CA (US); Martin Roscheisen, San Francisco, CA (US)

Correspondence Address: NANOSOLAR, INC., 5521 Hellyer Avenue, San Jose, CA, 95138, US

(73) Assignee: Nanosolar, Inc., Palo Alto, CA (US)

(21) Appl. No.: 11/465,787

(22) Filed: Aug. 18, 2006

(51) Int. Cl. H01L 31/042; B23K 3/00

(52) U.S. Cl. 136/244; 228/51

(57) ABSTRACT

Methods and devices are provided for improved large-scale solar installations. In one embodiment, a junction-box free photovoltaic module is used comprising of a plurality of photovoltaic cells and a module support layer providing a mounting surface for the cells. The module has a first electrical lead extending outward from one of the photovoltaic cells, the lead coupled to an adjacent module without passing the lead through a junction box. The module may have a second electrical lead extending outward from one of the photovoltaic cells, the lead coupled to another adjacent module without passing the lead through a junction box. Without junction boxes, the module may use connectors along the edges of the modules which can substantially reduce the amount of wire or connector ribbon used for such connections.

### FIELD OF THE INVENTION

This invention relates generally to photovoltaic devices, and more specifically, to solar cells and/or solar cell modules designed for large-scale electric power generating installations.

### BACKGROUND OF THE INVENTION

Solar cells and solar cell modules convert sunlight into electricity. Traditional solar cell modules are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar module to the installation site. A host of other materials are also included to make the solar module functional. This may include junction boxes, bypass diodes, sealants, and/or multi-contact connectors used to complete the module and allow for electrical connection to other solar modules and/or electrical devices. Certainly, the use of traditional silicon solar cells with conventional module packaging is a safe, conservative choice based on well understood technology.

Drawbacks associated with traditional solar module package designs, however, have limited the ability to install large numbers of solar panels in a cost-effective manner. This is particularly true for large scale deployments where it is desirable to have large numbers of solar modules setup in a defined, dedicated area. Traditional solar module packaging comes with a great deal of redundancy and excess equipment cost. For example, a recent installation of conventional solar modules in Pocking, Germany deployed 57,912 monocrystalline and polycrystalline-based solar modules. This meant that there were also 57,912 junction boxes, 57,912 aluminum frames, untold meters of cablings, and numerous other components. These traditional module designs inherit a large number of legacy parts that hamper the ability of installers to rapidly and cost-efficiently deploy solar modules at a large scale.

Although subsidies and incentives have created some large solar-based electric power installations, the potential for greater numbers of these large solar-based electric power installations has not been fully realized. There remains substantial improvement that can be made to photovoltaic cells and photovoltaic modules that can greatly reduce their cost of manufacturing, increase their ease of installation, and create much greater market penetration and commercial adoption of such products, particularly for large scale installations.

### SUMMARY OF THE INVENTION

Embodiments of the present invention address at least some of the drawbacks set forth above. The present invention provides for the improved solar module designs that reduce manufacturing costs and redundant parts in each module. These improved module designs are well suited for installation at dedicated sites where redundant elements can be eliminated since some common elements or features may be shared by many modules. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a junction-boxless photovoltaic module is used comprising of a plurality of photovoltaic cells and a module support layer providing a mounting surface for the cells. The module has a first electrical lead extending outward from one of the photovoltaic cells, the lead coupled to an adjacent module without passing the lead through a junction box. The module may have a second electrical lead extending outward from one of the photovoltaic cells, the lead coupled to another adjacent module without passing the lead through a junction box. Without junction boxes, the module may use connectors along the edges of the modules which can substantially reduce the amount of wire or connector ribbon used for such connections.

Optionally, the following may also be adapted for use with any of the embodiments disclosed herein. The module support layer may be frameless and thus creates a frameless photovoltaic module. The first electrical lead may be a nanoconnector. The second electrical lead may be a nanoconnector. The nanoconnector may have a length no more than about 2× a distance from one edge of the module to an edge of a closest adjacent module. The nanoconnector may have a length no more than about 2× a distance from one edge of the module to an edge of a closest adjacent module. The first electrical lead may extend outward from an edge of the module support layer along an outer perimeter of the module between module layers. The second electrical lead may extend outward from an edge of the module support layer along an outer perimeter of the module between module layers. The first electrical lead may extend outward through an opening in the module support layer. The first electrical lead may extend outward through an opening in the module support layer, wherein a distance of the opening from the edge of the module is no more than about 2× a distance from one edge of the module to an edge of a closest adjacent module. The second electrical lead may extend outward through an opening in the module support layer. The second electrical lead may extend outward through an opening in the module support layer, wherein a distance of the opening from the edge of the module is no more than about 2× a distance from one edge of the module to an edge of a closest adjacent module. The photovoltaic cell may have a metallic underlayer. The photovoltaic cell may be comprised of a thin-film photovoltaic cell. The first electrical lead may extend outward from one edge of the module and the second electrical lead may extend outward from a different edge of the module. The first electrical lead may extend outward from an opening in the module support layer along one edge of the module and the second electrical lead may extend outward from a second opening in the module support layer along a different edge of the module. A backsheet may be included, wherein the first electrical lead extends outward from an opening in the backsheet along one edge of the module and the second electrical lead extends outward from a second opening in the backsheet along a different edge of the module. A first cell in the module may be a dummy cell comprising of non-photovoltaic material to facilitate electrical connection to other solar cells in the module. Optionally, a flat, inline diode may take the place of one of the cells in the module.

In another embodiment of the present invention, a photovoltaic power installation is provided comprising of a plurality of frameless photovoltaic modules and a plurality of electrical leads from each of the modules. Adjacent modules may be coupled together by at least one of the electrical leads extending outward from the modules without passing through a junction box between adjacent modules.

Optionally, the following may also be adapted for use with any of the embodiments disclosed herein. The electrical leads may be comprised of nanoconnectors each having a length less than about 2× a distance separating adjacent modules. The modules may be coupled in a series interconnection. The modules may have a thermally conductive backsheet that can radiate heat. The modules may have a backsheet comprised of at least one layer of aluminum and at least one layer of alumina. The modules may be frameless and mounted on a plurality of rails. The modules may be frameless and mounted on a plurality of rails, wherein the rails carry electrical charge between modules.

In another embodiment of the present invention, a photovoltaic module is provided comprising of a transparent, protective coversheet and a multi-layer backsheet comprised of a) at least one structural layer and b) at least one electrically insulating layer. A plurality of photovoltaic cells may be located between the coversheet and the backsheet. In one nonlimiting example, the structural layer comprises of at least one layer of aluminum and the electrically insulating layer comprises of at least one alumina layer. Preferably, the insulating layer may be derived from or created in part from the structural layer, such as but not limited to anodization of the structural layer. This simplifies manufacturing and reduces cost.

Optionally, the following may also be adapted for use with any of the embodiments disclosed herein. A polymer layer may be used in contact with the backsheet to fill cracks or openings in the alumina layer. A silicone-based layer may be used in contact with the backsheet to fill cracks or openings in the alumina layer. The multi-layer back sheet may be comprised of a top layer of alumina, a bottom layer of alumina, and at least one layer of aluminum therebetween. The transparent coversheet may be comprised of glass. The transparent coversheet may be frameless, and this creates a frameless module. An edge seal may be included to act as a moisture barrier. A desiccant loaded edge seal may be used to act as a moisture barrier around the module.

In a still further embodiment of the present invention, a method is provided that comprises of providing a plurality of frameless, rigid photovoltaic modules. The plurality of photovoltaic modules may be mounted on a support element at the installation site. The photovoltaic modules are electrically coupled together at the installation site in a series interconnected manner, wherein electrically coupling comprises of using a tool to weld and/or solder at least one electrical lead from one module to an electrical lead of an adjacent module.

Optionally, the following may also be adapted for use with any of the embodiments disclosed herein. The electrically coupling step may be comprised of at least one of the following methods: welding, spot welding, reflow soldering, ultrasonic welding, arc welding, cold welding, laser welding, induction welding, or combinations thereof. Electrical leads may extend outward from the module without passing through a junction box. The electrical leads may join to form a V-shape, Y-shape, and/or U-shape.

In yet another embodiment of the present invention, a solar module connection tool is provided for use with solar modules having electrical leads, the tool comprising of a working end and a user handle end. The working end may define an interface receptacle for permanently joining an electrical lead from one module and an electrical lead from another module when the tool is activated. The tool may solder one lead to another lead to join the modules. Optionally, the tool uses at least one of the following techniques to join two electrical leads: welding, spot welding, reflow soldering, ultrasonic welding, arc welding, cold welding, laser welding, induction welding, or combinations thereof.

A further understanding of the nature and advantages of the invention will become apparent by reference to the remaining portions of the specification and drawings.

### BRIEF DESCRIPTION OF THE DRAWINGS

FIG. 1 is an exploded perspective view of an module according to one embodiment of the present invention.

FIG. 2 is a cross-sectional view of the embodiment of FIG. 1.

FIG. 3 is an exploded perspective view of a module according to another embodiment of the present invention.

FIG. 4 is a cross-sectional view of the embodiment of FIG. 3.

FIG. 5 is an exploded perspective view of a module according to yet another embodiment of the present invention.

FIG. 6 is a cross-sectional view of the embodiment of FIG. 5.

FIGS. 7 and 8 shows close-up cross-sectional views of seals on modules according to embodiments of the present invention.

FIG. 9 shows modules coupled together according to various embodiments of the present invention.

FIG. 10 shows a close-up view of an electrical connection on a module according to embodiments of the present invention.

FIG. 11 shows modules coupled together according to yet another embodiment of the present invention.

FIGS. 12 through 14 show support devices for mounting modules according to various embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Module

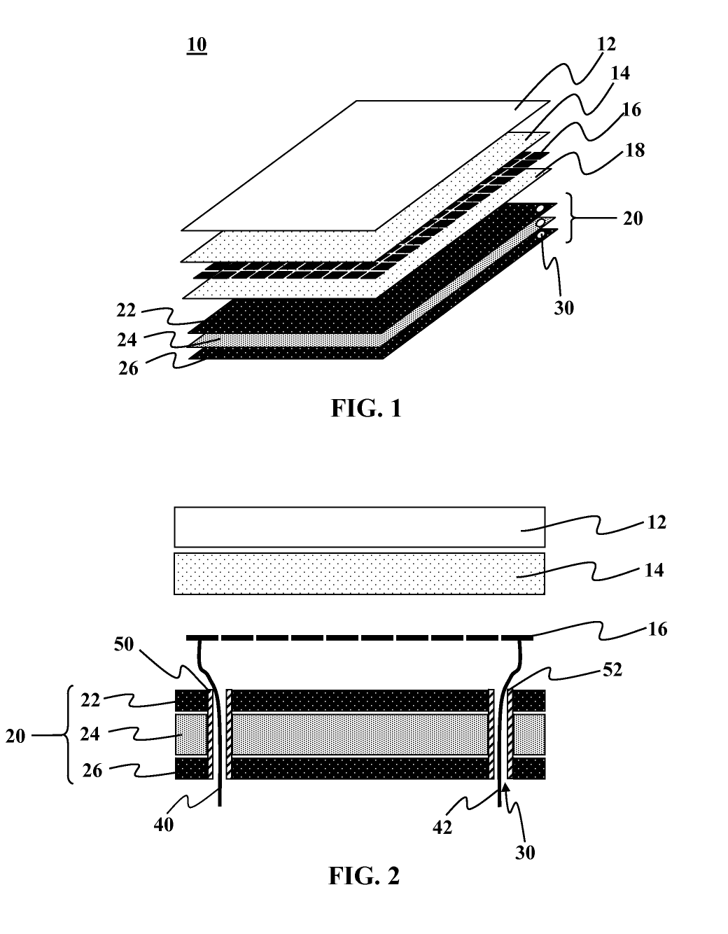

Referring now to FIG. 1, one embodiment of a module 10 according to the present invention will now be described. As module 10 is designed for large scale installation at sites dedicated for solar power generation, many features have been optimized to reduce cost and eliminate redundant parts. Traditional module packaging and system components were developed in the context of legacy cell technology and cost economics, which had previously led to very different panel and system design assumptions than those suited for increased product adoption and market penetration. The cost structure of solar modules includes both factors that scale with area and factors that are fixed per module. Module 10 is designed to minimize fixed cost per module and decrease the incremental cost of having more modules while maintaining substantially equivalent qualities in power conversion and module durability. In this present embodiment, the module 10 may include improvements to the backsheet, backsheet layout modifications, frame modifications, and electrical connection modifications.

FIG. 1 shows that the module 10 may include a rigid transparent upper layer 12 followed by a pottant layer 14 and a plurality of solar cells 16. Below the layer of solar cells 16, there may be another pottant layer 18 of similar material to that found in pottant layer 14. The transparent upper layer 12 provides structural support and acts as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. The total thickness of the glass or multi-layer glass may be in the range of about 2.0 mm to about 13 mm, optionally from about 2.8 mm to about 12 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16).

It should be understood that the simplified module 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots.

The present embodiment may use a simplified backsheet 20 that provides protective qualities to the underside of the module 10. As seen in FIG. 1, the backsheet 20 may be a multi-layer structure comprised of an electrically insulating layer 22, a support layer 24, and another electrically insulating layer 26. In the present embodiment, this may be comprised of an alumina layer 22, an aluminum layer 24, and an alumina layer 26. The alumina layers are optionally black in color to maximize emission of heat, particularly in the infrared spectrum. Optionally, some embodiments may only have one electrically insulating layer (either layer 22 or layer 26). The thickness of the alumina layer may be in the range of about 0.1 microns to about 100 microns, optionally about 0.3 microns to about 75 microns, and about 10 microns to about 75 microns. These layers are advantageous in that they may be formed in a straight forward process simultaneously on both sides of the aluminum layer 24. This reduces cost and the number of manufacturing steps. The alumina is also advantageous in that it is electrically insulating, but thermally conductive. Details of modules with thermally conductive backplanes and heat sinks can be found in commonly assigned, co-pending U.S. patent application Ser. No. ______ (Attorney Docket NSL-089) filed Aug. 18, 2006 and fully incorporated herein by reference for all purposes.

As seen in FIGS. 1 and 2, embodiments of the present invention may also design out per-module costs and minimizes per-area costs by eliminating the exterior support frame and junction box components, whose functions will instead be addressed at the system level through new mounting and wiring designs. By way of nonlimiting example as seen in FIG. 1, module 10 is designed to be a frameless module. Although frames may be useful in providing extra structural support during transport and installation, once the module 10 is installed much of the structural support comes from rails and other supports at the installation site. This is particularly true at large-scale installations where significant structural supports are already installed at the ground site prior to installing the solar modules. Accordingly, the frame becomes redundant once the module is installed on-site.

FIGS. 1 and 2 also show that the module 10 may be designed without the use of a junction box. FIG. 1 shows that openings 30 are made in the backsheet 20 to allow a wire or wire ribbon to extend outward from the module 10 or a solder connection to extend inward to a ribbon below. This outward extending wire or ribbon 40 or 42 may then be connected to another module, a solar cell in another module, and/or an electrical lead from another solar module to create an electrical interconnection between modules. Elimination of the junction box removes the requirement that all wires extend outward from one location on the module. Having multiple exit points allows those exits points to be moved closer to the objects they are connected to and this in turn results in significant savings in wire or ribbon length.

FIG. 2 shows a cross-sectional view of the junction box-less module 10 where the ribbons 40 and 42 are more easily visualized. The ribbon 40 may connect to a first cell in a series of electrically coupled cells and the ribbon 42 may connect to the last cell in the series of electrically coupled cells. As seen, the sidewalls of the openings 30 may have insulating layers 50 and 52 that prevent electrical contact between the ribbons 40 and the backsheet 20. The electrically insulating layers 50 and 52 are used when the backsheet 20 contains an electrically conductive layer which may be electrically charged if it contacts either of the wires or ribbons 40 and 42. Optionally, the wires or ribbons 40 and 42 may themselves have a coating or layer to electrically insulate themselves from the backsheet 20. FIG. 2 also shows that one of the pottant layers 14 or 18 may be optionally removed. Optionally, another protective layer may be applied to the alumina layer 26 improve the voltage withstand, fill pores/cracks, and/or alter the surface properties of that layer for improved protective qualities. The protective layer may be a polymer coating or layer that is dip coated, spray coated, or otherwise thinly deposited on the alumina layer 26. Optionally, the protective layer may be comprised of a polymer such as but not limited to fluorocarbon coating, perfluoro-octanoic acid based coating, or neutral polar end group, fluoro-oligomer, or fluoropolymer. Optionally, the protective layer may be comprised of a silicone based coating such as but not limited to polydimethyl siloxane with carboxylic acid or neutral polar end group, silicone oligomers, or silicone polymers. By way of nonlimiting example, the thickness may be in the range of about 1 micron to 100 microns, optionally about 2 to about 50 microns, or optionally about 3 to about 25 microns. Further details about other suitable protective layers can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the layer 26 can be found in commonly assigned, co-pending U.S. patent application Ser. No. ______ (Attorney Docket No. NSL-089) filed Aug. 18, 2006 and fully incorporated herein by reference for all purposes.

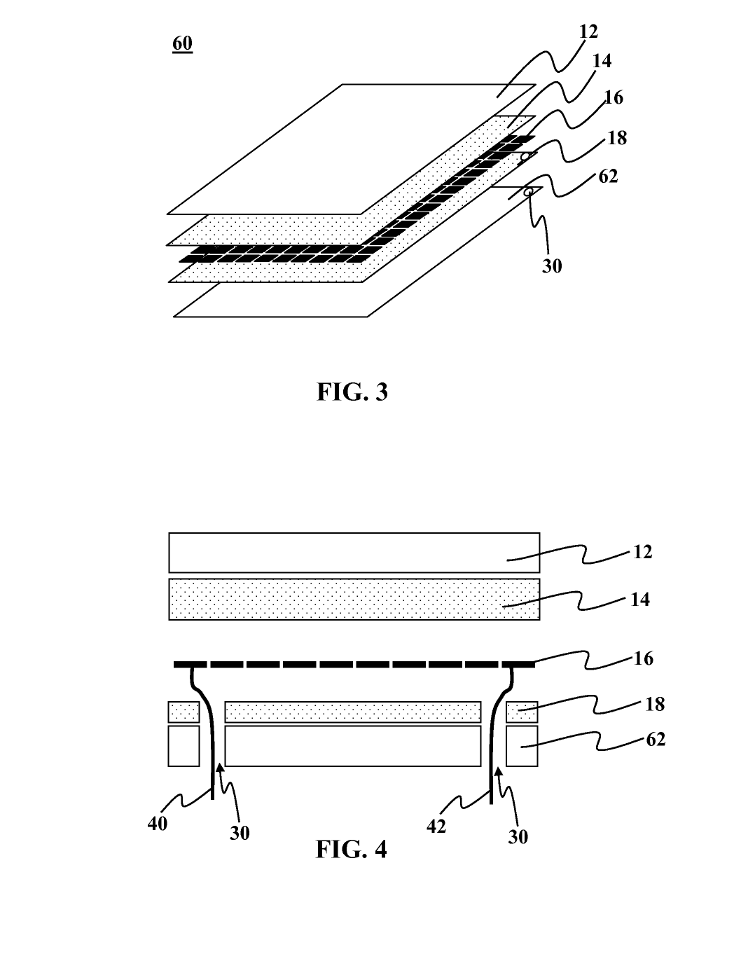

Referring now to FIG. 3, a variation on the module of FIG. 1 will now be described. FIG. 3 shows a module 60 where the multi-layer backsheet 20 may be replaced by a rigid backsheet 62 comprised of a material such as but not limited to annealed glass, heat strengthened glass, tempered glass, or similar materials are previously mentioned. Openings 30 may be formed to allow the ribbons 40 and 42 to extend outward from the backside of the module. The rigid backsheet 62 may be made of the same or different glass used to form the upper transparent layer 12. Optionally, in such a configuration, the top sheet 12 may be a flexible top sheet such as that set forth in U.S. patent application Ser. No. 60/806,096 (Attorney Docket No. NSL-085P) filed Jun. 28, 2006 and fully incorporated herein by reference for all purposes. The module 60 may continue to be a frameless, junction-boxless module with electrical connection schemes similar to that of module 10 in FIG. 1.

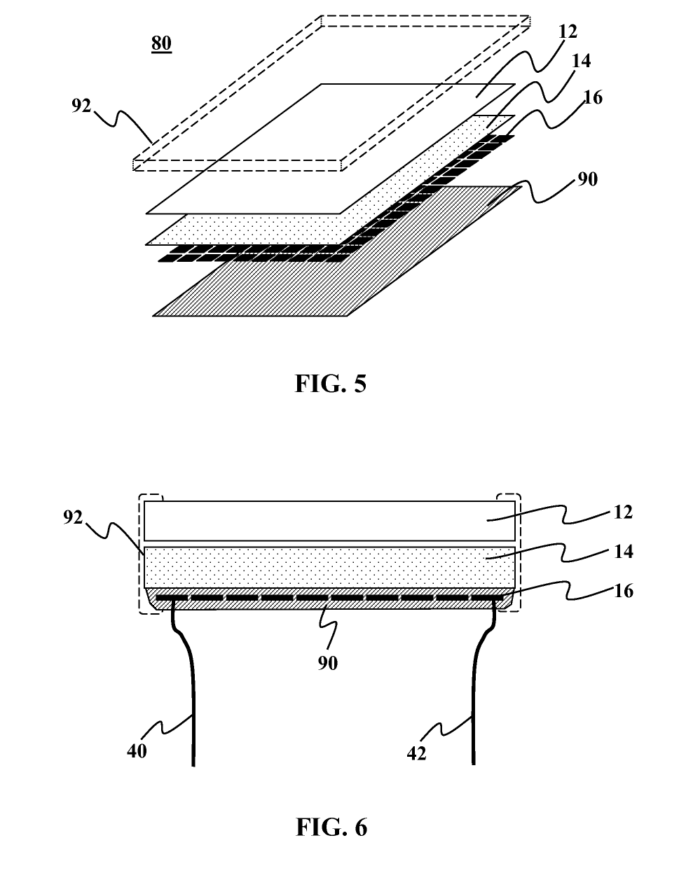

FIG. 4 shows a cross-sectional view of the module of FIG. 3. As can be seen, the sidewalls of the openings do not need to be insulated as the glass of backsheet 62 is not electrically conductive. By way of nonlimiting example, the thicknesses of backsheet 62 may be in the range of about 10 microns to about 1000 microns, optionally about 20 microns to about 500 microns, or optionally about 25 to about 250 microns. Again, as seen for FIG. 2, this module 60 is a frameless module without a junction box.

Referring now to FIG. 5, a still further variation on the module shown in FIG. 1 will now be described. FIG. 5 shows a module 80 with a rigid glass upper layer 12 followed by a pottant layer 14 and a plurality of solar cells 16. The pottant layer 14 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The backsheet 20 is replaced by a coating 90 the both encapsulates the solar cells 16 and provides an insulating layer. The coating 90 may be a sheet that is applied to the backside and then processed to adhere to the solar cells. Optionally, the coating 90 may be applied by various solution deposition techniques. The coating 90 may be comprised of one or more of the following materials: EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof. Optionally, another protective layer may be applied to the coating 90 to improve the scratch resistance and toughness of that layer. Further details about the protective layer can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the coating 90 can be found in commonly assigned, co-pending U.S. patent application Ser. No. ______ (Attorney Docket No. NSL-089) filed Aug. 18, 2006 and fully incorporated herein by reference for all purposes.

FIG. 6 shows a cross-sectional view of the module 80 more clearly showing how the coating 90 is situated relative to the solar cells 16. The coating 90 may surround the cells 16 to provide them protection and to provide exterior electrical insulation. The ribbons 40 and 42 may optionally exit the coating 90 from an underside orientation as shown in FIG. 6 or the ribbons 40 and 42 may exit in a side-way orientation (not shown). The use of a coating may eliminate the step of forming an opening in the backsheet as shown for the modules of FIGS. 2 and 4. It may also simplify the type of backing used with the current modules.

Optionally, as seen in FIGS. 5 and 6, a perimeter seal 92 (shown in phantom) may be applied around the module 80. This perimeter seal 92 will reinforce the barrier properties along the sides of the module 80 and prevent sideway entry of fluid into the module. The seal 92 may be comprised of one or more of the following materials such as but not limited to desiccant loaded versions of EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof. By way of nonlimiting example, the desiccant may be selected from porous internal surface area particle of aluminosilicates, aluminophosphosilicates, or similar material. It should be understood that the seal 92 may be applied to any of the modules described herein to reinforce their barrier properties. In some embodiments, the seal 92 may also act as strain relief for ribbons, wires, or other elements exiting the module. Optionally, the seal 92 may also be used to house certain components such as bypass diodes or the like which may be embedded in the seal material.

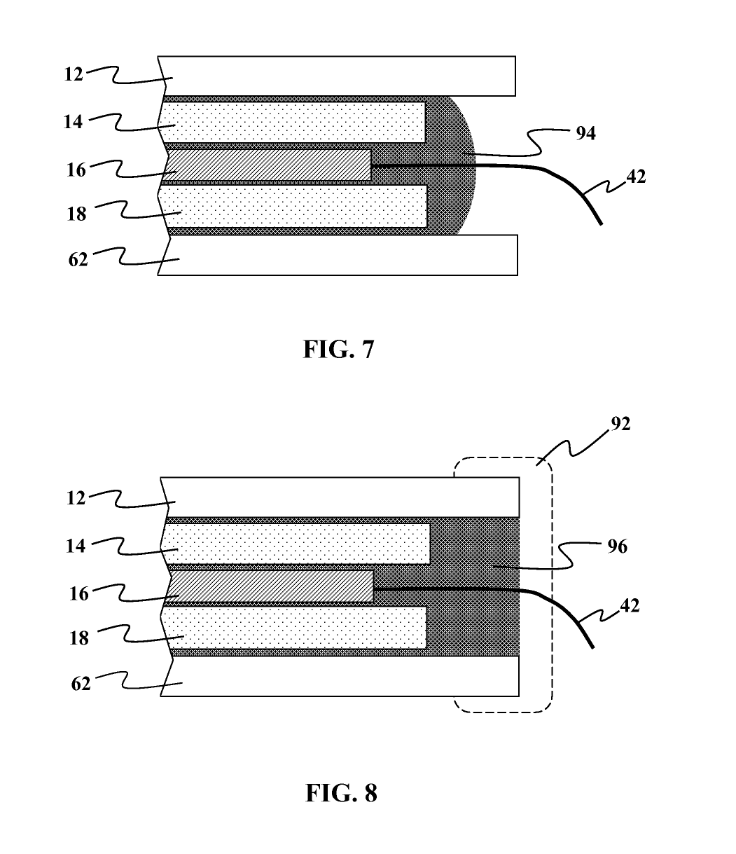

Referring now to FIGS. 7 and 8, it should be understood that the modules described herein are not limited to having connectors that exit through a backsheet of the module. As seen in FIG. 7, connectors can also be designed to exit along the sides of the module, between the various layers 14 and 18. This simplifies the issue of having to form openings in hardened, brittle substrates such as glass which may be prone to breakage if handled improperly during such procedures. As seen in FIG. 7, the solar cell 16 may be recessed so that moisture barrier material 94 may be applied along a substantial length of the edge of the module. This creates a longer seal area before moisture can reach the solar cell 16. The barrier material 94 may also act as a strain relief for the ribbon 42 extending outward from the module. By way of nonlimiting example, some suitable material for barrier material 94 include a high temperature thixotropic epoxy such as EPO-TEK® 353ND-T from Epoxy Technology, Inc., a ultraviolet curable epoxy such as EPO-TEK® OG116-31, or a one component, non-conductive epoxy adhesive such as ECCOSEAL™ 7100 or ECCOSEAL™ 7200 from Emersion & Cuming. In one embodiment, the materials may have a water vapor permeation rate (WVPR) of no worse than about 5×10⁻⁴ g/m² day cm at 50° C. and 100% RH. In other embodiments, it may be about 4×10⁻⁴ g/m² day cm at 50° C. and 100% RH. In still other embodiments, it may be about 3×10⁻⁴ g/m² day cm at 50° C. and 100% RH.

Referring now to FIG. 8, it is shown that in other embodiments, barrier material 96 may extend from the solar cell 16 to the edge of the module and create an even longer moisture barrier area. The ribbon 42 extends outward from the side of the module and the barrier material 96 may still act as an area of strain relief. A perimeter seal 92 may also be added to improve the barrier seal along the side perimeter of the module.

### Module Interconnection

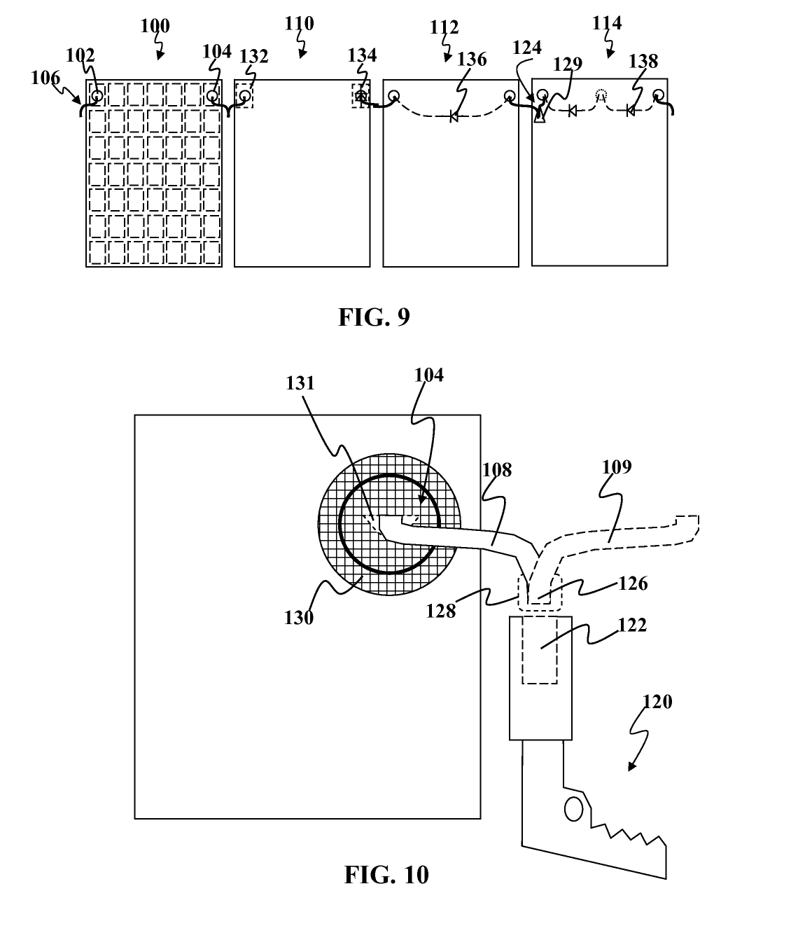

Referring now to FIG. 9, it should be understood that removal of the junction box, in addition to reducing cost, also changes module design to enable novel methods for electrical interconnection between modules. As seen in FIG. 9, instead of having all wires and electrical connectors extending out of a single junction box that is typically located near the center of the module, wires and ribbons from the module 100 may now extend outward from openings 102 and 104 along the edges of the module, closest to adjacent modules. The solar cells in module 100 are shown in phantom to show that the openings 102 and 104 are near the first and last cells electrically connected in the module. This substantially shortens the length of wire or ribbon need to connect one module to the other. The length of a connector 106 may be in the range of about 5 mm to about 500 mm, about 5 mm to about 250 mm, about 10 mm to about 200 mm or no more than 3× the distance between the closest edges of adjacent modules. Some embodiments have wire or ribbon lengths no more than about 2× the distance between the edges of adjacent modules. These short distance wires or ribbons may be characterized as nanoconnectors that may substantially decrease the cost of having many modules coupled together in close proximity, as would be the case at electrical utility installations designed for solar-based power generation

As seen in FIG. 9, the modules 100, 110, 112, and 114 may be series interconnected. This allows the power between modules to be added together in a manner typically preferred by most utilities running large scale solar module installations. Although not limited to the following, the modules 110, 112, and 114 typically include a plurality of solar cells and these are not shown for ease of illustration. Many more modules than those shown in FIG. 9 may be series interconnected in a repeating fashion similar to that in FIG. 9 to link large numbers of modules together. It should be understood that many number of modules (10s, 100s, 1000s, etc . . . ) may be coupled together in this manner. The end module may optionally be coupled to an inverter or other appropriate electrical device.

Referring now to FIG. 10, in addition to eliminating excess wire length, embodiments of the present invention may also eliminate the use of multi-contact connectors found in most existing modules. These multi-contact connectors are an added cost that provides a convenient, connection that can be joined without requiring dedicated tooling. Unfortunately, as the cost of a multi-contact connector is not insignificant, on very large-scale installations, it makes more economic sense to use simple connectors and a dedicated joining tool, rather than large number of expensive connectors just to avoid the use of tooling.

FIG. 10 shows a close-up view of module 100 with the opening 104 having a ribbon 108 extending outward from it. A ribbon 109 from an adjacent module is shown in phantom. The ribbons 108 and 109 will be interconnected by tool 120. By way of nonlimiting example, the ribbons may comprise of copper, aluminum, copper alloys, aluminum alloys, tin, tin-silver, tin-lead, solder material, nickel, gold, silver, noble metals, or combinations thereof. These materials may also be present as coatings to provide improved electrical contact. Tool 120 may use a variety of techniques to join the ribbons 108 and 109 together. Although not limited to the following, in one embodiment, the tool 120 may use a soldering technique to join the ribbons 108 and 109. The tool 120 may have a receptacle 122 for receiving the ends of the ribbons 108 and 109. Once the ends of the ribbons 108 and 109 are in the receptacle 122, the user activates tool 120 to solder the ribbons together and create the electrical interconnection. Optionally, in other embodiments, techniques such as welding, spot welding, reflow soldering, ultrasonic welding, arc welding, cold welding, laser welding, induction welding, or combinations thereof may be used. Soldering may involve using solder paste and/or solder wire with built-in flux.

As seen in FIG. 9 and 10, the resulting shape of the joined ribbons 108 and 109 may be similar to that of a V-shape, a Y-shape, or U-shape. The modules at one installation may one or more of these types of connection configuration. The extra length of provides slack form strain relief and to accommodate thermal expansion and contraction. Optionally, in another embodiment as seen in FIG. 9, the length of one ribbon may be longer than another ribbon so that the connection point 124 is beneath one of the modules. This provides better exposure protection for the connection point. This on-site soldering may be implemented with moisture protection around the ribbons 108 and 109. As seen in FIG. 10, some type of encapsulant such as but not limited to an epoxy, flexiblized epoxy, butyl rubber, silicone, electrical tape, harsh-environment electrical tape, polyurethane, hot melt olefin, acrylic, fluoropolymer, thermoplastic elastomer, amorphous polyester, heat shrink tubing, adhesive-filled heat shrink tubing, solder filled heat shrink tubing, or combinations thereof may be formed on or wrapped about the connection 126 to create a moisture proof barrier 128. In other embodiments, a shell connector may first be placed around connection 126 and then the shell connector may be filled with the encapsulant so that both the shell connector and the encapsulant provide protection. The shell-encapsulant combination may comprise of materials such as silicone gels, soft rubber, soft elastomer, or combinations thereof. The shell may be a clam-shell like structure with two openings that fit the ribbons. The connector 129 may be conical in shape as seen in FIG. 9 or it may take any of a variety of shapes including rectangular, oval, polygonal, the like, or combinations thereof. By way of nonlimiting example, the ribbons may be bare metal or they may be insulated wiring with ends that are exposed for soldering or optionally, insulated with a limited area on one surface exposed for soldering. The connector 129 may be free hanging or it may be adhered to the backside of the module.

FIG. 10 also shows that the opening may sealed by a large area of sealant 130 that covers the opening 104 and creates a protective barrier for the opening. The sealant 130 may form a circular patch as shown in FIG. 10 or it may be a square patch, oval patch, or other shaped patch. This creates a substantially flat backside connector that may allow for flat packing during transport of the modules. Optionally, additional strain relief 131 may be provided at the exit point of the ribbon from the module. The wire or ribbons passing through opening 104 contacts an aluminum patch right through to the back of an ending solar cell. The sealant 130 patches over the opening 104 in a manner so that there are some inches of contact and thus a humidity barrier. The module would then be contacted at these patches with additional aluminum stripes and some plastic around them. In some embodiments, to facilitate the connection, the cell in the module may be a dummy cell 132 (FIG. 9) e.g. with an optional flat bypass diode 134 to allow for easy connection of the ribbon 108. The flat bypass diode 134 may take the place of one of the cells in the module or it may be mounted on the backsheet beneath and/or outside the module. Some other embodiments may use an external in-line diode 136 between the ribbons to handle any issues of partial shading. FIG. 9 also shows an embodiment where one or more diodes 138 may optionally be used with one module.

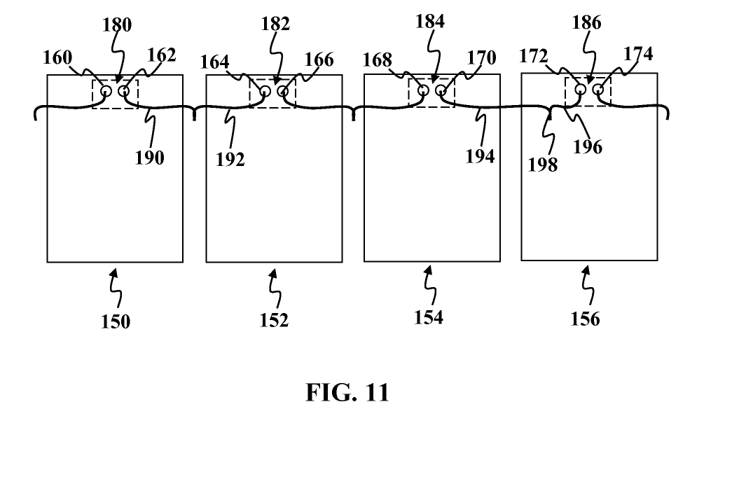

Referring now to FIG. 11, a variation on the module interconnection of FIG. 9 will now be described. The modules 150, 152, 154, and 156 are shown with openings 160, 162, 164, 166, 168, 170, 172, and 174 located near the center, away from adjacent modules. The modules may optionally include junction boxes 180, 182, 184, and 186. Even though these modules may optionally include a junction box, they may still advantageously use the simplified connector system described in FIG. 10. As seen in FIG. 11, the ribbons 190 and 192 may be of greater length, but the ends may be soldered or otherwise joined without using a more costly multi-contact connector. Optionally, as seen for ribbons 194 and 196, the length of one ribbon may be longer than the other so that the connection 198 is beneath one of the modules. The connection 198 may be adhered to the backside of the module for more efficient wire/connector management.

### Module Support

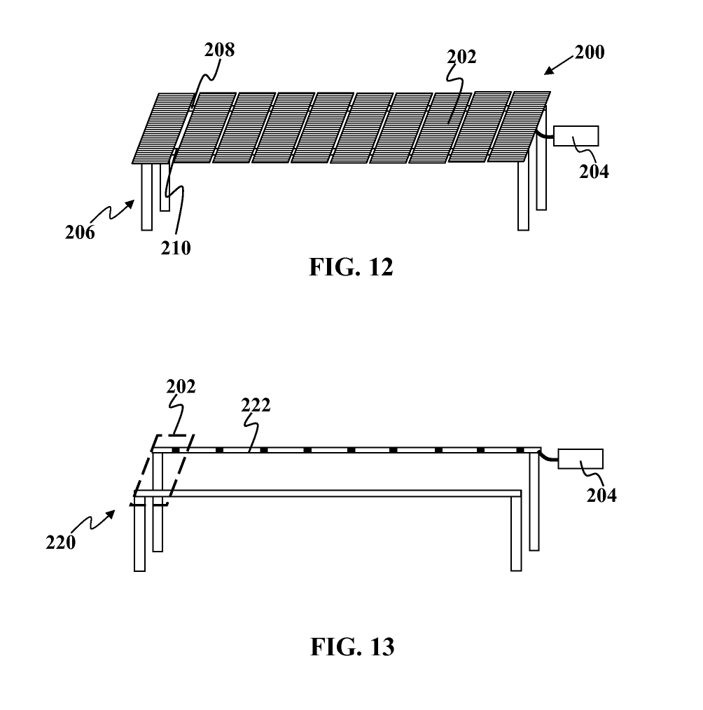

Referring now to FIG. 12, the mounting and supports used with the improved modules of the present application will now be described. FIG. 12 shows a photovoltaic electric power installation 200 with a plurality of modules 202 coupled to an inverter 204. Although not limited to the following, the modules 202 may be frameless modules which may use the interconnections as previously described. The modules may be mounted on a support 206 with rails 208 and 210. The rails 208 and 210 provide substantial support to the module and allows for a frameless module to be used. The modules may be oriented in landscape and/or portrait orientation on the support 206.

Referring now to FIG. 13, another embodiment of support is shown. In this embodiment, support 220 may further reduce the number of parts by electrifying the rail 222. The modules 202 may be electrically coupled to the rail 222 and power generated by each module is carried away by the rail. For series interconnection, the rail 222 may be electrically non-conductive areas 224 so that charge travels along the rail and must then pass through a module before reaching another conductive area of the rail. For parallel interconnection, substantially the entire rail 222 is conductive. Again, the modules may be oriented in landscape and/or portrait orientation on the support 220.

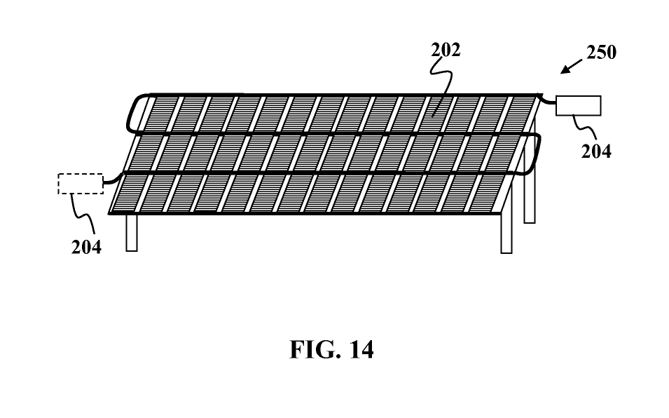

Referring now to FIG. 14, a still further embodiment of a support according to the present invention is shown. Support 250 shows that a plurality of rows of modules 202 may be mounted on the support. The rails used may be adapted to carry charge in a manner similar to that shown in FIG. 13. Optionally, the rails are merely structural or may act as conduits for wire or electrical connector management. Individual rows may be coupled to other rows by way external connectors 252 or optionally by use of electrified support rails. Optionally, one or more inverters 204 may be coupled to the photovoltaic modules.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, a heat sink may be coupled from the module to the rail to draw heat away from the modules. By way of nonlimiting example, the heat sink on the module may be a plain metal foil, a three-dimensional laminar structure for air cooling, a liquid based cooling vehicle, or combinations thereof. Although glass is the layer most often described as the top layer for the module, it should be understood that other material may be used and some multi-laminate materials may be used in place of or in combination with the glass. Some embodiments may use flexible top layers or coversheets. By way of nonlimiting example, the aluminum/alumina backsheet is not limited to rigid modules and may be adapted for use with flexible solar modules and flexible photovoltaic building materials. Embodiments of the present invention may be adapted for use with superstrate or substrate designs.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc . . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A junction-boxless photovoltaic module comprising:
a plurality of photovoltaic cells;
a module support layer providing a mounting surface for the cells;
a first electrical lead extending outward from one of the photovoltaic cells, the lead coupled to an adjacent module without passing the lead through a junction box; and
a second electrical lead extending outward from one of the photovoltaic cells, the lead coupled to another adjacent module without passing the lead through a junction box.

2. The module of claim 1 wherein the module support layer is frameless and this creates a frameless photovoltaic module.

3. The module of claim 1 wherein the first electrical lead is a nanoconnector.

4. The module of claim 1 wherein the second electrical lead is a nanoconnector.

5. The module of claim 4 wherein the nanoconnector has a length no more than about 2× a distance from one edge of the module to an edge of a closest adjacent module.

6. The module of claim 5 wherein nanoconnector has a length no more than about 2× a distance from one edge of the module to an edge of a closest adjacent module.

7. The module of claim 1 wherein the first electrical lead extends outward from an edge of the module support layer along an outer perimeter of the module between module layers.

8. The module of claim 1 wherein the second electrical lead extends outward from an edge of the module support layer along an outer perimeter of the module between module layers.

9. The module of claim 1 wherein the first electrical lead extends outward through an opening in the module support layer.

10. The module of claim 1 wherein the first electrical lead extends outward through an opening in the module support layer, wherein a distance of the opening from the edge of the module is no more than about 2× a distance from one edge of the module to an edge of a closest adjacent module.

11. The module of claim 1 wherein the second electrical lead extends outward through an opening in the module support layer.

12. The module of claim 1 wherein the second electrical lead extends outward through an opening in the module support layer, wherein a distance of the opening from the edge of the module is no more than about 2× a distance from one edge of the module to an edge of a closest adjacent module.

13. The module of claim 1 wherein the photovoltaic cell has a metallic underlayer.

14. The module of claim 1 wherein the photovoltaic cell comprises of a thin-film photovoltaic cell.

15. The module of claim 1 wherein the first electrical lead extends outward from one edge of the module and the second electrical lead extend outward from a different edge of the module.

16. The module of claim 1 wherein the first electrical lead extends outward from an opening in the module support layer along one edge of the module and the second electrical lead extends outward from a second opening in the module support layer along a different edge of the module.

17. The module of claim 1 further comprising a backsheet, wherein the first electrical lead extends outward from an opening in the backsheet along one edge of the module and the second electrical lead extends outward from a second opening in the backsheet along a different edge of the module.

18. The module of claim 1 wherein a first cell in the module comprises is a dummy cell comprising of non-photovoltaic material to facilitate electrical connection to other solar cells in the module.

19. The module of claim 1 wherein a flat, inline diode takes the place of one of the cells in the module.

20. A photovoltaic power installation comprising:
a plurality of frameless photovoltaic modules;
a plurality of electrical leads from each of the modules;
wherein adjacent modules are coupled together by at least one of the electrical leads extending outward from the modules without passing through a junction box between adjacent modules.

21-42. (canceled)
